(19) United States
(12) Patent Application Publication
(10) Pub. No.: US 2026/0173539 A1
(43) Pub. Date: Jun. 18, 2026

(54) LATERAL SEMICONDUCTOR CONTROL RECTIFIER DEVICE WITH DIRECT BACKSIDE CONTACT

(71) Applicant: INTERNATIONAL BUSINESS MACHINES CORPORATION, ARMONK, NY (US)

(72) Inventors: Anindya Nath, Watervliet, NY (US); Robert Gauthier, Williston, VT (US); Masoud Zabihi, Schenectady, NY (US); Anthony I-Chih Chou, Guilderland, NY (US)

(21) Appl. No.: 18/981,350

(22) Filed: Dec. 13, 2024

(51) Int. Cl. H10D 89/60; H10D 10/80; H10D 30/00; H10D 64/01; H10D 64/23; H10D 84/01; H10D 84/40

(52) U.S. Cl. CPC H10D 89/713; H10D 64/01; H10D 64/231; H10D 84/0109; H10D 84/401; H10D 10/821; H10D 30/501

(57) ABSTRACT

A semiconductor device includes a first doped region and a second doped region, the first doped region and the second doped region located on frontside of the semiconductor device, a first well region below the first doped region, a second well region below the second doped region, a third doped region below the first well region, a fourth doped region below the second well region, a first backside contact below the third doped region, and a second backside contact below the fourth doped region. The first backside contact and the second backside contact are configured to connect the third doped region and the fourth doped region to a backside of the semiconductor device, respectively.

### BACKGROUND

### Technical Field

The present disclosure generally relates to semiconductors, and more particularly, to lateral semiconductor control rectifier device with backside contact structure, and methods of creation thereof.

### Description of Related Art

The continuous miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. Various functionalities, including processing and storage, are increasingly being integrated within a single chip, enabling more compact and efficient systems.

### SUMMARY

According to an embodiment, a semiconductor device includes a first doped region and a second doped region, the first doped region and the second doped region located on frontside of the semiconductor device, a first well region below the first doped region, a second well region below the second doped region, a third doped region below the first well region, a fourth doped region below the second well region, a first backside contact below the third doped region, and a second backside contact below the fourth doped region. The first backside contact and the second backside contact are configured to connect the third doped region and the fourth doped region to a backside of the semiconductor device, respectively.

In one embodiment, the semiconductor device includes a bottom dielectric layer (BILD) encapsulating the first backside contact and the second backside contact, a first metal contact below the first backside contact, a second metal contact below the second backside contact, and a backside interconnect below the semiconductor device.

In one embodiment, the semiconductor device includes a set of gate regions between the first doped region and the second doped region, shallow trench isolation (STI) below the first doped region and the second doped region, and interlayer dielectric (ILD) on the frontside of the semiconductor device. The ILD and the STI are configured to isolate the first doped region from contact with the second doped region.

In one embodiment, the semiconductor device includes a first contact and a second contact over the first doped region and the second doped region. The first contact and the second contact connect the first doped region and the second doped region to the frontside of the semiconductor device, respectively.

In one embodiment, the semiconductor device is electrically connected to a back end of line (BEOL) through a set of vias.

In one embodiment, the semiconductor device includes spacer over sidewalls of the first metal contact and the second metal contact. The spacer is configured to isolate the first metal contact and the second metal contact from contact with the BILD.

In one embodiment, each of the first doped region and the second doped region further includes alternative layers extended horizontally between two adjacent gate regions.

In one embodiment, the alternative layers include silicon.

In one embodiment, the semiconductor device includes two vertical bipolar junction transistors (BJT).

In one embodiment, the semiconductor device includes vertically isolated by a low-k interlayer dielectric.

According to an embodiment, a method of fabricating a semiconductor device includes forming a first doped region and a second doped region located on frontside of the semiconductor device, forming a first well region below the first doped region, forming a second well region below the second doped region, flipping the wafer and forming a third doped region below the first well region, forming a fourth doped region below the second well region, forming a first backside contact below the third doped region, forming a second backside contact below the fourth doped region, and establishing an electrical connection between the first backside contact and the second backside contact to the backside of the semiconductor device via the third doped region and the fourth doped region, respectively.

In one embodiment, the method includes forming a bottom dielectric layer (BILD) encapsulating the first backside contact and the second backside contact, forming a first metal contact below the first backside contact, forming a second metal contact below the second backside contact, and forming a backside interconnect below the semiconductor device.

In one embodiment, the method includes forming a set of gate regions between the first doped region and the second doped region, forming shallow trench isolation (STI) below the first doped region and the second doped region, forming interlayer dielectric (ILD) on the frontside of the semiconductor device, and isolating the first doped region from contact with the second doped region via the ILD and the STI.

In one embodiment, the method includes forming a first contact and a second contact over the first doped region and the second doped region, and connecting the first doped region and the second doped region to the frontside of the semiconductor device via the first contact and the second contact, respectively.

In one embodiment, the semiconductor device is electrically connected to a back end of line (BEOL) through a set of vias.

In one embodiment, the method includes forming spacer over sidewalls of the first metal contact and the second metal contact, and isolating the first metal contact and the second metal contact from contact with the BILD via the spacer.

In one embodiment, each of the first doped region and the second doped region further includes alternative layers extended horizontally between two adjacent gate regions.

In one embodiment, the alternative layers include silicon.

In one embodiment, forming the first backside contact and the second backside contact includes a low-temperature epitaxial deposition at the backside of the semiconductor device.

According to an embodiment, a semiconductor device includes a lateral bipolar junction transistor (BJT), and a vertical heterojunction bipolar transistor (HBT) coupled to the lateral BJT. A collector of the vertical HBT is wired to a backside interconnect on a backside of the semiconductor device, and the semiconductor device is vertically isolated by a low-k interlayer dielectric.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates a conventional semiconductor device, in accordance with some embodiments.

FIG. 2A illustrates two vertical bipolar junction transistors, in accordance with some embodiments.

FIG. 2B illustrates a vertical heterogenous bipolar transistor and a lateral bipolar junction transistor, in accordance with some embodiments.

FIG. 3 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

Backside interconnect technology is increasingly becoming the industry's favored approach for managing complex integrated circuits, largely driven by the need to improve device density, reduce interconnect delays, and enhance power delivery efficiency. Traditional frontside wiring schemes, while mature and widely adopted, are running into scaling and congestion challenges as advanced semiconductor nodes push toward ever smaller geometries and more complex device architectures. By contrast, employing the backside of the wafer for routing metal layers and contacts opens up new spatial and design freedoms, allowing logic, memory, and power delivery to be optimized in ways not previously achievable using frontside-only methodologies.

Beyond just improving circuit routing and power distribution, direct backside connection technology stands out as a key enabler for advanced device engineering. One particularly promising avenue lies in the integration of low-temperature epitaxial (epi) layers on the wafer's backside. The ability to deposit and tailor these semiconductor layers at relatively low thermal budgets is crucial, as it avoids excessive thermal cycling that could degrade frontside device performance or introduce unwanted diffusion of dopants. With careful engineering of doping levels, material compositions, and junction profiles, these backside epi layers can serve as functional platforms for creating an entirely new class of lateral Electrostatic Discharge (ESD) devices.

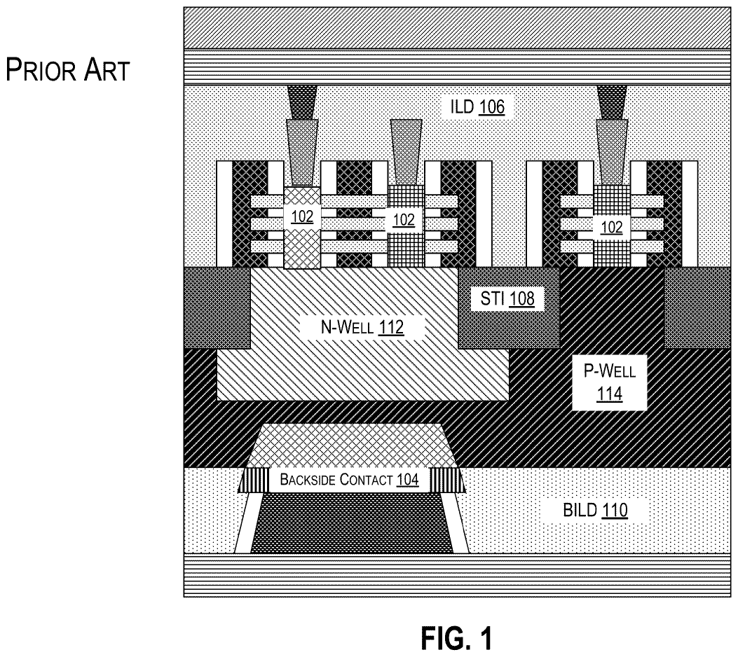

Traditionally, ESD protection structures have been confined to the frontside of the wafer, where they compete with active circuitry for valuable real estate and often limit design choices due to their large footprint and integration complexity. With backside interconnects, designers can exploit the backside epi layers to define lateral conduction paths that serve as ESD current shunts, protection diodes, thyristor-like structures, or triggerable transistor elements, all engineered without encroaching on the frontside circuitry. This spatial decoupling offers the potential to significantly increase the density, variety, and customization of ESD protection devices. FIG. 1 illustrates a conventional semiconductor device, in which a doped region 102 acts as an anode and the backside contact 104 acts as the cathode. In such a device, in case of an electrostatic discharge (ESD) event, the current flows from the doped region 102 on the frontside of the semiconductor device to the backside contact 104 on the backside of the semiconductor device. The conventional semiconductor device can include ILD 106, STI 108, BILD 110, an N-well 112 and a P-well 114.

By controlling the doping profiles, junction depths, and layer thicknesses in the backside epi, it is possible to tune the turn-on characteristics, trigger voltages, and holding voltages of these lateral ESD elements. Different doping gradients and material stacks can yield a range of conduction mechanisms, avalanche breakdown behaviors, and snapback conditions, thereby allowing a single wafer process to support a diverse “menu” of ESD device types. Some devices might turn on at relatively low voltages to protect extremely sensitive analog circuits, while others may exhibit higher holding voltages suitable for robust power and I/O line protection. This versatility not only improves the ESD robustness of the integrated circuit but can also simplify the qualification and binning of products by providing selectable ESD options without altering front-side layouts.

In essence, the combination of backside interconnects and low-temperature backside epi integration is poised to revolutionize how ESD protection is designed and implemented. By shifting a traditionally frontside-only problem into a three-dimensional design space, manufacturers gain both new degrees of freedom and a significantly enhanced toolkit for protecting sensitive electronic components from static discharge events. As technology nodes continue to scale and performance targets become ever more demanding, the backside engineering approach provides a forward-looking strategy to maintain device reliability, improve functionality, and push the boundaries of what is possible in semiconductor chip design.

Disclosed is a lateral semiconductor controlled rectifier with direct backside contact, which can a solid-state switching device designed to handle high current and voltage levels while maintaining a compact and efficient layout. In such a structure, the flow of current takes place predominantly parallel to the surface plane of the semiconductor wafer rather than through its thickness. Active regions, including the controlling junctions and conduction paths, can be formed side-by-side within the plane of the wafer. This arrangement is in contrast to vertical devices, where current flows from the top surface through to the bottom of the substrate.

The direct backside contact feature introduces a conductive pathway at the rear surface of the wafer, enabling improved current handling and potentially reduced on-resistance. By leveraging a direct contact at the wafer's backside, the semiconductor device can achieve a more efficient current return path without competing for space on the top surface, which frees up valuable real estate on the front side of the wafer for additional circuitry or more complex device architectures, making it possible to integrate the controlled rectifier into high-density integrated circuits. Furthermore, incorporating a backside contact can help simplify thermal management, since heat generated during operation can more readily dissipate through the backside, enhancing the device's overall reliability and stability.

By employing a lateral semiconductor controlled rectifier architecture and incorporating a direct backside contact, the disclosed semiconductor device allows for a more refined balance between performance, integration density, and thermal efficiency, and represents an advancement in device engineering, catering to evolving demands in modern electronics that require robust power control and protection components without sacrificing precious chip area or energy efficiency.

Accordingly, the teachings herein provide methods and systems of lateral semiconductor control rectifier device formation with the direct backside contact. The techniques described herein may be implemented in a number of ways. Example implementations are provided below with reference to the following figures.

### Example Lateral Semiconductor Control Rectifier with Direct Backside Contact Structure

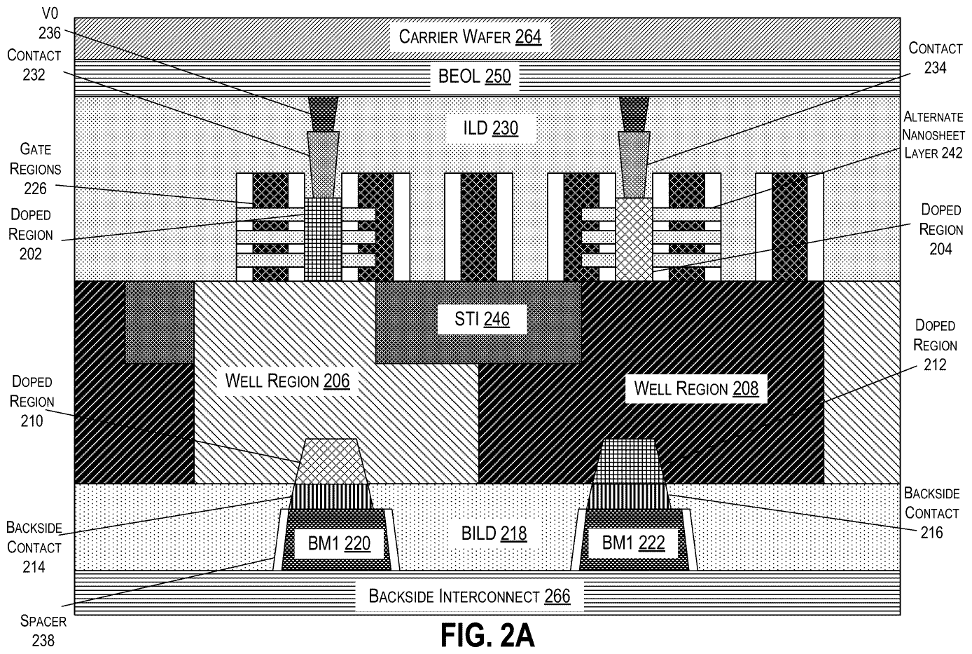

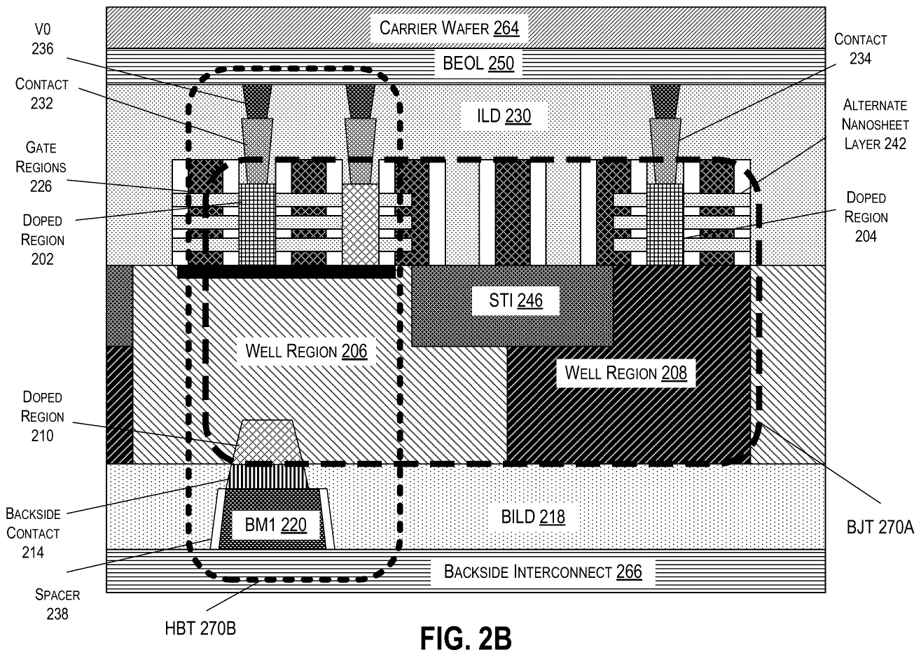

Reference now is made to FIG. 2A, which is a simplified cross-section view of a semiconductor device, consistent with an illustrative embodiment. The semiconductor device includes a first doped region 202 and a second doped region 204 situated on the frontside of the semiconductor device. A doped region is a portion of the semiconductor substrate, such as silicon, into which specific impurities known as dopants have been introduced to alter its electrical properties. Doping can be accomplished using ion implantation or diffusion processes. In ion implantation, dopant atoms such as boron, phosphorus, arsenic, or antimony are accelerated into the semiconductor surface at controlled energies and doses. Diffusion involves placing a dopant source near the wafer and heating the system so the dopant atoms diffuse into the substrate.

In some embodiments, at least one doped region is doped with an N-type dopant by utilizing donor elements such as phosphorus or arsenic, which have five valence electrons. Introducing the donors into silicon, which typically has four valence electrons, adds extra electrons that increase the electron concentration and make the region conductive with negative charge carriers. In some embodiments, at least one doped region is doped with a P-type dopant by utilizing acceptor elements such as boron, which have three valence electrons. When incorporated into silicon, boron creates “holes,” or positively charged carriers, by lacking a complete electron bond. The relative concentration and choice of dopants determines the electrical resistivity, carrier mobility, and conduction mechanism of each doped region.

Below the first doped region 202 is a first well region 206, and below the second doped region 204 is a second well region 208. A well region can be formed by selectively doping a portion of the substrate to a particular type and concentration, creating a defined electrical well or basin for carriers. For example, an N-well might be formed by implanting phosphorus at a certain dose and annealing to achieve a uniform doping profile. A P-well would use boron or another p-type dopant. Wells define the basic structure of transistors and other devices by providing a stable, controlled doping environment in which channels, junctions, and depletion regions can form.

Beneath the first well region 206 is a third doped region 210 and beneath the second well region 208 is a fourth doped region 212. The additional doped regions can serve numerous purposes, such as forming part of a vertical transistor stack, providing a buried layer for latch-up prevention, or creating junctions that support certain device functionalities such as electrostatic discharge (ESD) protection or specialized rectifier structures. The doping concentration, dopant choice, and depth profiles are carefully engineered to achieve the intended electrical characteristics. The doping concentration can vary widely, from lightly doped at around 10\hat{ }15 dopant atoms per cubic centimeter for forming transistor channels to heavily doped at or above 10\hat{ }19 dopant atoms per cubic centimeter for forming ohmic contacts and low-resistance conduction paths.

Below the third doped region 210 is a first backside contact 214 and below the fourth doped region 212 is a second backside contact 216. A backside contact provides a conductive pathway on the opposite side of the wafer from the frontside circuitry. By placing contacts on the backside, the crowding on the front surface can be reduced, which results in simplify routing, and potentially improving electrical performance and heat dissipation. Backside contacts can be formed by depositing or bonding a conductive material, such as a metal stack containing titanium, tungsten, aluminum, or copper, directly onto the wafer's backside. The metals are chosen for their low resistivity, adhesion to semiconductor materials, and interface properties.

In some embodiments, the semiconductor device further includes a bottom dielectric layer, BILD 218, encapsulating the first backside contact 214 and the second backside contact 216. A bottom dielectric layer can be made from an insulating material such as silicon dioxide or a more advanced low-k dielectric. The purpose of the BILD 218 can be to isolate conductive elements electrically, prevent unwanted current leakage, and protect the underlying semiconductor substrate. Below the first backside contact 214, a first metal contact 220, BM1 220, can be formed, and below the second backside contact 216, a second metal contact 222, BM1 222, can be formed. The first metal contact 220 and the second metal contact 222 serve as robust terminals for connecting the doped regions to other parts of the circuitry or external packages. The metal contacts are fabricated by depositing and patterning thin films of metals with good conductivity and thermal stability. The choice of metals and the thickness of these layers can be optimized to reduce (e.g., minimize) resistance and reduce electromigration.

A backside interconnect 266 may lie below the semiconductor device, providing lateral routing for signals and power lines on the wafer's underside, which can alleviate routing complexity on the frontside and enable more compact device layouts. The backside interconnect is formed by depositing and patterning multiple metallic layers separated by insulating dielectrics, much like the back end of line interconnects on the frontside, but implemented on the wafer's backside for improved three-dimensional integration.

On the frontside, a set of gate regions 226 is located between the first doped region 202 and the second doped region 204. A gate region typically involves a gate dielectric layer and a conductive gate material, formerly polysilicon, now often a metal gate, that modulates the conduction channel in underlying semiconductor layers. When a voltage is applied to the gate, it alters the energy bands and carrier concentrations in the adjacent semiconductor channel, allowing precise control over current flow. The gate regions define transistor action, enabling amplification, switching, and logic operations.

Shallow trench isolation, STI 246, extends below the first doped region 202 and the second doped region 204. STI 246 is formed by etching narrow, shallow trenches into the silicon substrate and filling them with an oxide or another insulating material. The process electrically isolates neighboring devices, preventing unwanted current leakage and cross-talk between circuit elements. The presence of STI 246 ensures that each active device region operates independently, improving yield, performance, and reliability.

An interlayer dielectric, ILD 230, is deposited on the frontside of the semiconductor device to provide vertical isolation between successive layers of interconnects and devices. ILD 230 can be composed of silicon dioxide, silicon nitride, or low-k materials that reduce capacitance between metal lines. Reducing interconnect capacitance is important for increasing signal speed and lowering power consumption.

A first contact 232 can be formed over the first doped region 202 and a second contact 234 can be formed over the second doped region 204 to provide frontside access. The contacts are small conductive vias or plugs that penetrate one or more layers of dielectric to reach the underlying doped regions. The contacts are typically formed using metal deposition and patterning techniques. The choice of contact metal, such as tungsten or copper, influences the contact resistance and reliability.

In some configurations, the semiconductor device is electrically connected to a back end of line, BEOL 250, through a set of vias 236. The BEOL 250 includes multiple layers of thin metal wires and interlayer dielectrics that route signals and power across the chip. The set of vias 236 are vertical connections between these metal layers. Accessing the BEOL 250 through the set of vias 236 allows the device to integrate seamlessly into a larger integrated circuit, supporting increased complexity and functionality.

A spacer 238 can be deposited over the sidewalls of the first metal contact 220 and the second metal contact 222. Spacer can include thin layers of insulating material, formed by a conformal deposition and anisotropic etch process. The spacer 238 ensure that the metal contacts remain properly isolated from the bottom dielectric layer, BILD 218, and from one another, preventing electrical shorts and improving the device's long-term reliability.

In some embodiments, each of the first doped region 202 and the second doped region 204 can further include alternative nanosheet layers 242, also referred to as nanosheet gates 226, that extend horizontally between two adjacent gate regions. The alternative layers, also referred to as nanosheet gates NS, can be formed from silicon or from other semiconductor alloys, and can be engineered with specific doping profiles, thicknesses, and strain conditions. The alternative nanosheet layers 242 allow fine-tuning of threshold voltages, carrier mobility, and other parameters crucial for optimizing transistor performance. For example, incorporating silicon germanium (SiGe) in a channel region can enhance hole mobility, and using strained silicon can improve electron mobility, thereby boosting transistor drive current.

Additionally, the semiconductor device can be vertically isolated by the ILD 230, which can be a low-k interlayer dielectric. The low-k dielectric has a dielectric constant lower than that of traditional silicon dioxide, reducing the parasitic capacitance between adjacent metal lines. This leads to faster signal propagation, reduced dynamic power consumption, and improved overall device performance.

In some embodiments, the semiconductor device incorporates two vertical bipolar junction transistor (BJT) structures, one configured as NPN and the other as PNP. A bipolar junction transistor is a three-terminal device consisting of emitter, base, and collector regions with distinct doping polarities. In an NPN transistor, the emitter and collector are typically doped with an N-type dopant, introducing excess electrons as majority carriers, while the base is lightly doped with a P-type dopant, providing holes as minority carriers. In a PNP transistor, the doping scheme is reversed: the emitter and collector are P-type and the base is N-type. By arranging these transistors along a vertical axis—meaning the emitter, base, and collector are stacked in a vertical direction rather than spread out laterally—the device can achieve a high degree of integration density and potentially offer improved current handling and switching characteristics. Vertical BJTs can conduct currents that flow perpendicular to the wafer surface, enabling efficient use of the available silicon area and potentially improving performance metrics such as gain and frequency response.

In some embodiments, the well contacts, e.g., the backside contacts, that provide electrical access to the well regions of the semiconductor device are formed by depositing a low-temperature epitaxial (epi) layer on the backside of the wafer. Low-temperature epitaxy refers to the process of growing a crystalline semiconductor layer at relatively low substrate temperatures, often a few hundred degrees Celsius rather than the higher temperatures (typically above 900° C.) used for conventional epitaxy. By lowering the temperature during epitaxial growth, the process can reduce thermal stress and limit dopant diffusion, maintaining precise doping profiles and junction depths. The low-temperature epi layer can be doped in situ—meaning dopants are introduced as the layer is grown—to create well contacts that extend from the backside of the device down to the underlying doped regions. The epitaxially formed well contacts help ensure good electrical conductivity and reliable ohmic connections, while reducing (e.g., minimizing) any adverse thermal effects on the other device layers.

Once the well contacts are established, they can be wired to a backside interconnect, often located in the backside interconnect, which consists of multiple metal and dielectric layers deposited and patterned after the front-end transistor formation is complete. By connecting the well contacts to the backside interconnect layers, the semiconductor device can route signals, ground references, or power lines behind the active transistor regions. The three-dimensional (3D) integration approach helps reduce frontside routing complexity, increase circuit density, and potentially improve electrical performance by shortening conduction paths and reducing resistance and parasitic inductances. In some embodiments, the semiconductor device includes a carrier wafer 264 to bond to other devices. And a backside interconnect 266.

Reference now is made to FIG. 2B, which is a simplified cross-section view of a semiconductor device including a vertical heterogenous bipolar transistor and a lateral bipolar junction transistor, consistent with an illustrative embodiment. The semiconductor device includes a lateral bipolar junction transistor, the lateral BJT 270A. A bipolar junction transistor is a three-terminal device composed of emitter, base, and collector regions, each doped to create P-type or N-type domains that govern the flow of charge carriers. A lateral BJT arranges these regions side-by-side along a horizontal plane of the semiconductor substrate. In the case of a lateral PNP transistor, the emitter and collector are P-type regions and the base is N-type. Lateral BJTs allow current to flow parallel to the wafer surface, making them suitable for certain analog or control circuit functions where planar integration is advantageous.

Coupled to the lateral BJT 270A is a vertical heterojunction bipolar transistor, the vertical HBT 270B. A heterojunction bipolar transistor is similar to a BJT which is formed using two or more different semiconductor materials with dissimilar bandgaps. The heterojunction design can improve carrier injection efficiency, reduce base transit time, and provide higher current gain and frequency response than a homojunction BJT. The vertical HBT 270B can be constructed such that current flows perpendicular to the wafer surface. The vertical orientation can reduce the footprint of the transistor and often allows for higher current densities and better high-frequency performance.

In some embodiment, the vertical HBT 270B is of the NPN configuration, where the emitter and collector regions are N-type and the base region is P-type. The heterojunction occurs at the base-emitter interface. By selecting an appropriate material, such as a SiGe (silicon-germanium) alloy with a tailored germanium concentration, the base region can have specific bandgap properties. For example, a low-doped P-type SiGe base can enhance carrier transport while maintaining excellent gain and frequency characteristics. The introduction of germanium modifies the lattice structure and band alignment in a controlled manner, thereby improving carrier injection into the base and boosting the transistor's overall performance.

A defining characteristic of the vertical HBT 270B in this device is that its collector region is formed by depositing a low-temperature N+ epitaxial (epi) layer on the backside of the wafer. Epitaxy involves growing a crystalline semiconductor layer on top of a substrate. By using a low-temperature process (typically a few hundred degrees Celsius), the growth reduces unwanted diffusion of dopants and preserves sharp doping profiles. N+ doping indicates a highly doped N-type region, which ensures that the collector has a low resistivity and can handle high current densities. Placing such a heavily doped collector region at the backside leverages the vertical structure to optimize current flow and reduce frontside clutter.

The collector of the vertical HBT 270B is wired to a backside interconnect, often part of the BEOL metallization. The BEOL 250 can include a series of metal layers and interlayer dielectrics deposited after the transistor fabrication steps are complete. The layers form the wiring system that interconnects transistors and other components in an integrated circuit. The backside wiring can include metallization schemes and vertical vias to reach upper-level metal layers, thereby creating a three-dimensional integration platform that enhances performance and density.

The entire semiconductor device can be vertically isolated by a low-k interlayer dielectric. Interlayer dielectric, ILD 230, can be an insulating material placed between layers of metal interconnects to prevent electrical shorts and reduce parasitic capacitances. Low-k dielectric can have a dielectric constant (k value) lower than that of silicon dioxide, meaning they store less charge and thus contribute to lower parasitic capacitances between metal lines. Such a reduction in capacitance translates to faster signal propagation, lower dynamic power consumption, and improved signal integrity. Vertically isolating the semiconductor device with low-k materials helps ensure that the frontside and backside structures do not electrically interfere with each other, and that lateral and vertical transistors remain well-defined and stable over temperature and operational stress conditions.

In some embodiments, the semiconductor device can function as a semiconductor control rectifier. A semiconductor control rectifier (SCR) is a four-layer device that can function as a switch or rectifying element. By integrating a vertical HBT (NPN type) and a lateral BJT (PNP type) in a single structure, the device can form a regenerative feedback loop that resembles the functionality of a thyristor or SCR. When triggered, the SCR can switch from a non-conductive state to a conductive state, allowing large currents to pass through. The combination of vertical and lateral transistor geometries, along with heterojunction engineering, can provide a robust and versatile current control solution suitable for power electronics, ESD protection, or other applications requiring controlled conduction paths.

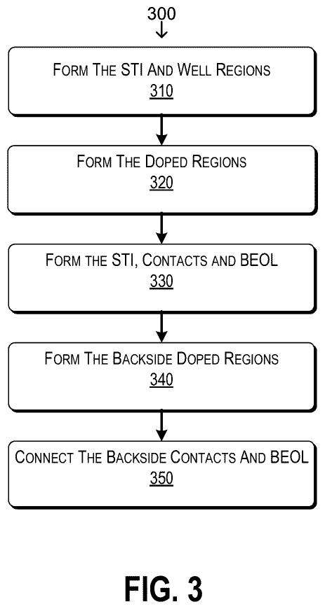

FIG. 3 illustrates a block diagram of a method 300 for forming the semiconductor device, in accordance with some embodiments. As shown by block 310, well regions are formed.

As shown by block 320, doped regions are formed.

As shown by block 330, the STI, contacts and BEOL are formed.

As shown by block 340, the BILD is formed.

As shown by block 350, the spacer is formed.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a first doped region and a second doped region, the first doped region and the second doped region located on a frontside of the semiconductor device;
a first well region below the first doped region;
a second well region below the second doped region;
a third doped region below the first well region;
a fourth doped region below the second well region;
a first backside contact below the third doped region; and
a second backside contact below the fourth doped region, wherein the first backside contact and the second backside contact are configured to connect the third doped region and the fourth doped region to a backside of the semiconductor device, respectively.

2. The semiconductor device of claim 1, wherein the semiconductor device further comprises:
a bottom dielectric layer (BILD) encapsulating the first backside contact and the second backside contact;
a first metal contact below the first backside contact;
a second metal contact below the second backside contact; and
a backside interconnect below the semiconductor device.

3. The semiconductor device of claim 1, further comprising:
a set of gate regions between the first doped region and the second doped region;
shallow trench isolation (STI) in the first well region and in-between the first doped region and the second doped region; and
an interlayer dielectric (ILD) on the frontside of the semiconductor device, wherein the ILD and the STI are configured to isolate the first doped region from contact with the second doped region.

4. The semiconductor device of claim 1, further comprising:
a first contact and a second contact over the first doped region and the second doped region, wherein the first contact and the second contact connect the first doped region and the second doped region to the frontside of the semiconductor device, respectively.

5. The semiconductor device of claim 1, wherein the semiconductor device is electrically connected to a back end of line (BEOL) through a set of vias.

6. The semiconductor device of claim 2, further comprising:
a spacer over sidewalls of the first metal contact and the second metal contact, wherein the spacer is configured to isolate the first metal contact and the second metal contact from contact with the BILD.

7. The semiconductor device of claim 1, wherein each of the first doped region and the second doped region further comprises alternative nanosheet layers extended horizontally between two adjacent gate regions.

8. The semiconductor device of claim 7, wherein the alternative nanosheet layers include silicon.

9. The semiconductor device of claim 1, wherein the semiconductor device comprises two vertical bipolar junction transistors (BJT).

10. The semiconductor device of claim 1, wherein the semiconductor device is vertically isolated by a low-k interlayer dielectric.

11. A method of fabricating a semiconductor device, the method comprising:
forming STI regions;
forming a first well region;
forming a second well region;
forming a first doped region and a second doped region located on a frontside of the semiconductor device;
flipping wafer and forming a third doped region below the first well region;
forming a fourth doped region below the second well region;
forming a first backside contact below the third doped region;
forming a second backside contact below the fourth doped region; and
establishing an electrical connection between the first backside contact and the second backside contact to a backside of the semiconductor device via the third doped region and the fourth doped region, respectively.

12. The method of claim 11, further comprising:
forming a bottom dielectric layer (BILD) encapsulating the third doped region, the fourth doped region, the first backside contact and the second backside contact;
forming a first metal contact below the first backside contact;
forming a second metal contact below the second backside contact; and
forming a backside interconnect below the semiconductor device.

13. The method of claim 11, further comprising:
forming a set of gate regions between the first doped region and the second doped region;
forming shallow trench isolation (STI) below the first doped region and the second doped region;
forming interlayer dielectric (ILD) on the frontside of the semiconductor device; and
isolating the first doped region from contact with the second doped region via the ILD and the STI.

14. The method of claim 11, further comprising:
forming a first contact and a second contact over the first doped region and the second doped region; and
connecting the first doped region and the second doped region to the frontside of the semiconductor device via the first contact and the second contact, respectively.

15. The method of claim 11, wherein the semiconductor device is electrically connected to a back end of line (BEOL) through a set of vias.

16. The method of claim 12, further comprising:
forming spacer over sidewalls of the first metal contact and the second metal contact; and
isolating the first metal contact and the second metal contact from contact with the BILD via the spacer.

17. The method of claim 11, wherein each of the first doped region and the second doped region further comprises alternative nanosheet layers extended horizontally between two adjacent gate regions.

18. The method of claim 17, wherein the alternative nanosheet layers include silicon.

19. The method of claim 11, wherein forming the first backside contact and the second backside contact comprises a low-temperature epitaxial deposition at the backside of the semiconductor device.

20. A semiconductor device, comprising:
a lateral bipolar junction transistor (BJT); and
a vertical heterojunction bipolar transistor (HBT) coupled to the lateral BJT, wherein a collector of the vertical HBT is wired to a backside interconnect on a backside of the semiconductor device, and the semiconductor device is vertically isolated by a low-k interlayer dielectric.
